(19) United States
(12) Patent Application Publication
(10) Pub. No.: US 2007/0212860 A1
(43) Pub. Date: Sep. 13, 2007

(54) METHOD FOR CRYSTALLIZING A SEMICONDUCTOR THIN FILM

(75) Inventors: Toshio Fujino, Kanagawa (JP); Akio Machida, Kanagawa (JP); Tadahiro Kono, Tokyo (JP)

Correspondence Address: BELL, BOYD & LLOYD, LLP, P. O. BOX 1135, CHICAGO, IL, 60690, US

(73) Assignee: SONY CORPORATION, Tokyo (JP)

(21) Appl. No.: 11/684,908

(22) Filed: Mar. 12, 2007

(30) Foreign Application Priority Data
Mar. 13, 2006 (JP) P2006-067270
Dec. 21, 2006 (JP) P2006-344129

(51) Int. Cl. H01L 21/20; H01L 21/36

(52) U.S. Cl. 438/487

(57) ABSTRACT

A method for crystallizing a semiconductor thin film is provided. The method includes continuously irradiating an energy beam on a semiconductor thin film while scanning at a given speed, wherein the semiconductor thin film is completely melted and the irradiation conditions of the energy beam are so set that the semiconductor thin film at a central position of the energy beam is finally crystallized in association with the scanning with the energy beam.

### CROSS REFERENCES TO RELATED APPLICATIONS

The present application claims priority to Japanese Patent Application JP 2006-067270 filed on Mar. 13, 2006 and Japanese Patent Application JP 2006-344129, filed in the Japanese Patent Office on Dec. 21, 2006, the entire contents of which are being incorporated herein by reference.

### BACKGROUND

This invention relates to a method for crystallizing a semiconductor thin film by irradiation of an energy beam.

In flat displays such as liquid crystal displays and organic EL devices using organic electroluminescent elements, thin film transistors (TFT) have been in use as switching elements for an active matrix display of a plurality of pixels. The thin film transistor is classified into TFT using polysilicon (poly-Si) as an active region (polysilicon TFT) and TFT using amorphous silicon (amorphous Si) as an active region (amorphous silicon TFT).

Of these, the polysilicon TFT has the feature that it has carrier mobility that is ten to one hundred times greater than the amorphous silicon TFT and the degradation of on current is smaller. Thus, the polysilicon TFT not only has the very excellent characteristics as a switching element for the displays, but also has attracted an attention as a switching element for various types of logic circuits (e.g. a domino logic circuit and a CMOS transmission gate circuit) and also as a component of multiplexers, EPROM, EEPROM, CCD and RAM using these circuits.

For a making technique of such a polysilicon TFT, a so-called low temperature polysilicon process making use of a low temperature process of about 600° C. or below has been developed to realize low-cost fabrication of substrate. In the low temperature polysilicon process, there has been widely used a pulse laser crystallization technique wherein a pulse laser whose oscillation time is very short is used to crystallize an amorphous silicon film. The pulse laser crystallization technique is one wherein properties of silicon are utilized in such a way that a silicon film on a substrate is instantaneously melted by irradiation with a high-output pulse laser and is crystallized during the course of solidification thereof.

For instance, in the low temperature polysilicon process using an excimer laser, while a line-shaped laser beam is moved little by little to allow the beams to be mostly overlapped, an amorphous silicon film is subjected to pulse irradiation in such a way that laser beam irradiation on the same portion is repeated 10 to 20 times. In doing so, there is obtained polysilicon whose grain size becomes uniform over the entire surface of an active region. Moreover, there has been proposed a method wherein crystal grains are controlled in position by crystallization using an SLS (sequential lateral solidification) technique. For instance, the phase of an excimer laser beam is spatially modulated through a phase shift mask to permit the irradiating laser beam to have an energy density gradient, with which the position of crystal grains is controlled (see “Surface Science 21”, 2000, vol. 1, No. 5, pp. 278-287)

In recent years, with respect to such flat panel displays as set out above, a high frame rate liquid crystal display is being developed for the purpose of further improving a moving image characteristic and a contrast characteristic, and also a new type of display including a self-emitting display such as an organic EL display or the like is under development. This entails a demand for development, as a switching element adaptable for such displays as mentioned above, of a TFT, which is substantially fee of characteristic degradation upon abrupt passage of a great current and a characteristic variation among switching elements is small.

In this connection, although the polysilicon TFT obtained according to such a known low temperature polysilicon process as set out above are very advantageous in that it has the likelihood of passing a relatively great current with a great carrier mobility and is small in characteristic degradation, an element-to-element characteristic especially of an initial threshold voltage or an on current varies more greatly when compared with an amorphous silicon TFT. The element-to-element characteristic variation of the polysilicon TFTs becomes a factor of causing uneven brightness in a display using the polysilicon TFT as a switching element.

Such an element-to-element characteristic variation in the polysilicon TFT as set forth above depends on the variation in number of grain boundaries existing in a channel direction (i.e. a direction along which electrons flow) in a channel portion of the polysilicon TFT. Accordingly, within a range where grain boundaries are small in number, a great variation of TFT elements takes place depending on the difference even in small number of grain boundaries. On the other hand, as the number of grain boundaries increases, the variation of the TFT elements is suppressed to a low level even if the number of grain boundaries at the channel portion differs slightly. In this sense, in order to suppress the characteristic variation in the polysilicon TFTs to a low level, importance is placed on the formation of a polysilicon film wherein relatively small-sized crystals with a uniform shape are regularly aligned or arrayed.

However, the excimer laser that has been widely used in the pulse laser crystallization technique set out hereinabove is a kind of gas laser, for which interpulse energy stability is low. Accordingly, although laser beam irradiation is carried out repeatedly on the same portion ten to twenty times in order to obtain polycrystals whose grain size becomes uniform, the uniformity of the size of the resulting crystal grains is not satisfactory. Moreover, the unit cost of the excimer laser is high and the running cost required for replacement of a laser tube (oscillator) is also high. The repetition of about several tens of irradiation cycles as set out above is necessary and thus, the throughput becomes low, with the attendant problem that the production costs cannot be lowered.

The problem that the crystal grain size cannot be satisfactorily made uniform likely occurs in the foregoing method using a phase shift mask. Additionally, according to the latter method, a high cost for the fabrication of the phase shift mask is required, with an additional problem in that a difficulty is involved in making a large-sized substrate.

A method of explosive crystallization using a spot beam laser such as of Ar gas is a recrystallization method using solid phase transition, so that the resulting crystals are poor in quality and a satisfactory carrier mobility cannot be obtained.

### SUMMARY

It is preferable to provide a method for crystallizing a semiconductor thin film wherein crystal grains that have a good shape accuracy and are good in quality are regularly aligned, so that a crystal region exhibiting a good accuracy and a high carrier mobility can be formed.

In an embodiment, the present application provides a method for crystallizing a semiconductor thin film by continuously irradiating an energy beam on a semiconductor thin film while scanning at a given speed. In the method, the semiconductor thin film is completely melted and the irradiation conditions of the energy beam are so set that the thin film at a central position of the energy beam is finally crystallized in association with the scanning with the energy beam.

According to the method for crystallizing a semiconductor thin film, crystal grains that are so shaped as to be protruded toward a scanning direction of the energy beam in a state of being pulled toward a side of a scanning center are polycrystallized so that the crystal grains are regularly aligned along the scanning direction. The shape and alignment pitch of the crystal grains are appropriately controlled according to the irradiation conditions such as a scanning speed, irradiation energy and the like of the energy beam. Additionally, the crystal grains are those obtained by completely melting the semiconductor thin film by irradiation of the energy beam, followed by recrystallization by liquid phase growth. Thus, the quality of the crystals is good.

As stated above, according to the method for crystallizing a semiconductor thin film according to one embodiment of the invention, crystal grains that are good in shape accuracy and quality are regularly aligned, thus enabling one to form, in the semiconductor thin film, a polycrystalline region wherein a high carrier mobility is controlled in high accuracy. The use of the thus formed polycrystalline region makes it possible to obtain a thin film transistor adapted for a pixel switching element whose characteristic variation is effectively suppressed.

Additional features and advantages are described herein, and will be apparent from, the following Detailed Description and the figures.

### BRIEF DESCRIPTION OF THE FIGURES

FIG. 1 is a plan view illustrating a crystallization method according to one embodiment of the present invention;

FIGS. 2A to 2C are, respectively, a schematic view showing a sequence of steps of crystal growth according to the crystallization method of one embodiment of the present invention;

FIG. 3 is a plan view illustrating the crystallization method of one embodiment of the present invention;

FIGS. 4A and 4B are, respectively, a plan view illustrating a step in a method for manufacturing a semiconductor device using the crystallization method of one embodiment of the present invention;

FIG. 5 is a plan view showing a step subsequent to FIG. 4B;

FIG. 6 is an enlarged plan view of portion A in FIG. 5;

FIG. 7 is a plan view illustrating crystallization of a plurality of active regions;

FIG. 8 is a sectional view taken along line X-X′ in FIG. 5; and

FIGS. 9A and 9B are, respectively, a schematic view showing a step of manufacturing a liquid crystal display using a thin film semiconductor device.

### DETAILED DESCRIPTION

Embodiments are described with reference to the accompanying drawings. In the following embodiments, a method of crystallizing a semiconductor thin film and a method for manufacturing a thin film semiconductor device using the crystallization method are illustrated in this order.

<Method of Crystallizing a Semiconductor Thin Film>

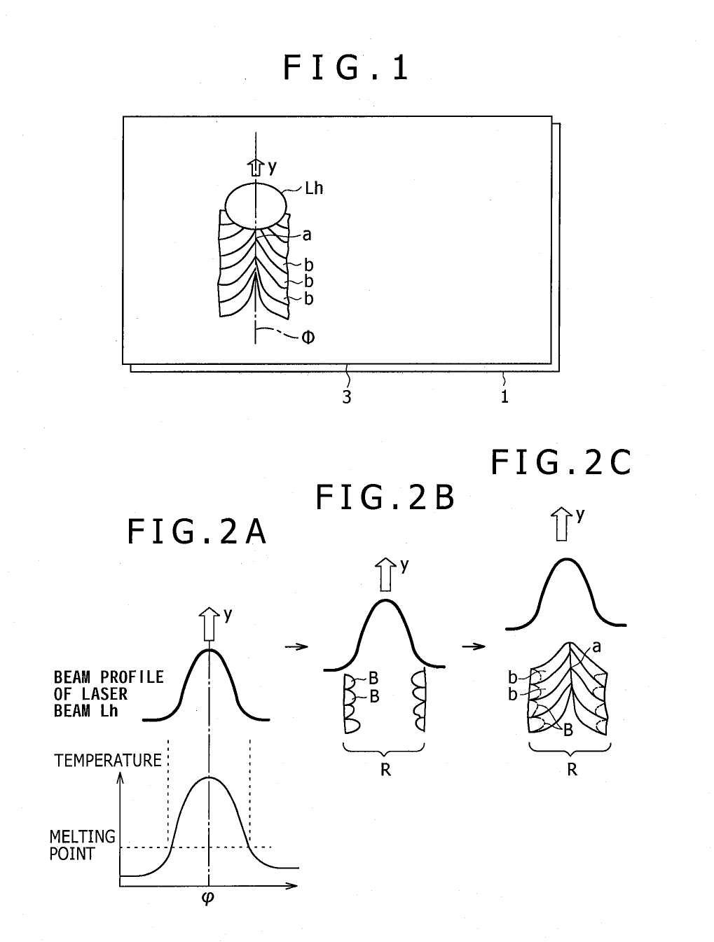

Initially, as shown in FIG. 1, a substrate 1 for forming a thin film semiconductor device is provided. For the substrate 1, there are used not only a silicon substrate, but also amorphous substrates such as a glass substrate, low melting substrates such as plastic substrates, substrates such as of quartz, sapphire and the like, metal substrates such as aluminium, a stainless steel and the like. It will be noted that although not shown in the figure, an insulating film such as an oxide film, a nitride film or the like may be formed on one main surface of the substrate 1 as a buffer layer serving to prevent thermal conduction to the substrate 1, and various types of metal films may also be formed.

Next, an amorphous semiconductor thin film 3 is formed on the substrate 1. For instance, the semiconductor thin film 3 made of amorphous silicon is formed herein according to a PE-CVD (plasma enhancement-chemical vapor deposition) method. The resulting semiconductor thin film 3 consists of so-called hydrogenated amorphous silicon (a-Si:H) containing a large amount of hydrogen. The thickness of the thus formed semiconductor thin film 3 is, for example, at 20 nm to 100 nm.

It is to be noted that in so far as there is used a method capable of suppressing a film-forming temperature to a low level, the formation of the semiconductor thin film 3 is not limited to the PE-CVD method, and may be carried out by a coating method. In the latter case, a mixture of a polysilane with a solvent is applied onto the substrate 1 to form a film, followed by drying and annealing to form the semiconductor thin film 3. According to film-forming methods capable of suppressing a film-forming temperature to a low level such as the former PE-CVD method and the coating method set out above, there can be obtained the semiconductor thin film 3 made of hydrogenated amorphous silicon (a-S:H) containing about 0.5 atomic % to 15 atomic % of hydrogen, which may vary more or less depending on film-forming conditions in either case.

Thereafter, a so-called dehydrogenation annealing treatment is carried out for desorbing excess hydrogen ions from the semiconductor thin film 3, if necessary. For such a dehydrogenation annealing treatment, furnace annealing, for example, at 400° C. to 600° C. is carried out. If a subsequent annealing treatment for crystallization is conducted while controlling an irradiation energy so as to eliminate excess hydrogen from a portion irradiated with a laser beam without gasification and expansion of hydrogen ions in the semiconductor thin film 3, the dehydrogenation annealing treatment may be omitted.

Subsequently, a laser beam Lh is irradiated, as an energy beam, on an active region set on the semiconductor thin film 3.

The laser beam Lh includes, for example, a GaN laser (wavelength: 405 nm), a Kr laser (wavelength: 413 nm), an Ar laser (wavelengths: 488 nm, 514.5 nm) and a second harmonic (532 nm) and a third harmonic (355 nm) of a Nd:YAG laser (wavelength: 1.06 μm), a second harmonic (524 nm) or a third harmonic (349 nm) of a Nd:YLF laser (wavelength: 1.05 μm), and a second harmonic (515 nm) or a third harmonic (344 nm) of a Yb:YAG laser (wavelength: 1.03 μm). Besides, a fundamental wave (792 nm) or a second harmonic (396 nm) of a Ti:sapphire laser may be used.

The semiconductor thin film 3 is irradiated with the laser beam Lh at a given speed in one scanning direction y while scanning. Especially, importance is placed on the setting of irradiation conditions of the laser beam Lh in conformity with the thickness of the semiconductor thin film 3 so that the semiconductor thin film 3 is completely melted along the depth thereof by irradiation of the laser beam Lh.

To this end, the wavelength of the laser beam Lh irradiated on the semiconductor thin film 3 is so selected based on the thickness and absorption coefficient of the semiconductor thin film 3 as to provide a relatively small coefficient of absorption sufficient to enable the beam to be absorbed in an entire area along the depth thereof without absorption only in the surface layer of the semiconductor thin film 3. More particularly, if the semiconductor thin film 3 is made of 50 nm thick amorphous silicon, for instance, a laser beam having a wavelength of 350 nm to 470 nm is preferably used. For an oscillation source of a laser beam Lh having such a wavelength as indicted above, mention is made, for example, of a GaN compound semiconductor laser oscillator or a YAG laser oscillator.

Irradiation conditions other than the wavelength of the laser beam Lh set out above, e.g. a numerical aperture NA of an objective lens through which the laser beam Lh is irradiated, a scanning speed of the laser beam Lh, an irradiation energy and the like, are controlled, thereby enabling the semiconductor thin film to be completely melted along the depth and crystallized. The irradiation of the laser beam Lh with a predetermined intensity or over on the amorphous semiconductor leads to complete melting of the semiconductor thin film 3.

In the crystallization step, the laser beam Lh whose wavelength has been so selected as mentioned above is used as a spot beam whose beam profile is in a Gaussian form. This entails, as shown in FIG. 2A, a temperature of a portion irradiated with the laser beam Lh which corresponds to a Gaussian form of a beam profile of the laser beam Lh and becomes highest at a scanning center φ of the laser beam Lh and lowest at opposite ends.

As shown in FIG. 2B, when the laser beam Lh is irradiated while scanning in the scanning direction y, crystallization and solidification commence from positions, which are most distance from the scanning center φ in a scanning path R where the semiconductor thin film 3 has been completely melted, (i.e. opposite side ends of the scanning path R of the laser beam). Eventually, a given number of crystal species B occur at the opposite side ends of the scanning path R.

As shown in FIG. 2C, as the scanning with the laser beam Lh further proceeds, solidification is in progress in a state where the crystal species B are pulled toward the scanning direction y and also toward the scanning center φ, and crystallization finally occurs at the scanning center φ. At this stage, the scanning speed and output of the laser beam Lh may be appropriately controlled within the range of such irradiation conditions as set out above so as to permit solidification to be completed at the scanning center φ. In this way, there are obtained crystal grains b in a semi-crescent form broadened from the scanning center φ toward opposite sides of the scanning path R, or in the form of a crescent that is axisymmetrically divided into halves. At the scanning center φ where the solidification is completed, a series of grain boundaries are formed along the scanning direction y.

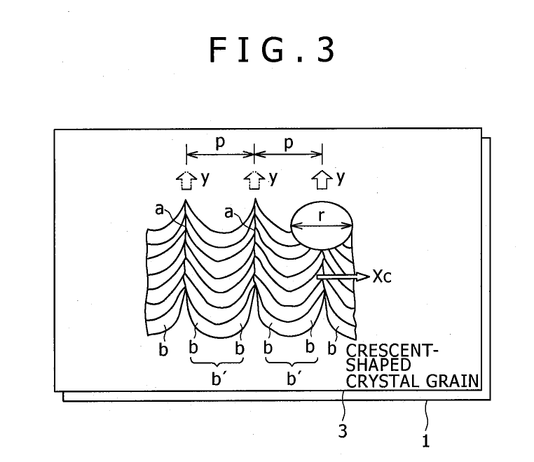

In the crystallization step, as shown in FIG. 3, the laser beams Lh are scanned in parallel to one another on the semiconductor thin film 3 on the substrate 1 while being kept at given pitches p. In individual scanning cycles, the scanning directions y are kept in a given direction.

The scanning pitch p between the laser beams Lh is set within such a range that the scanning center φ is not overlapped with a scanning path R of an adjacent laser beam Lh and solidification proceeds inherently to take over the crystallinity of crystal grains b formed at the scanning position of the adjacent laser beam Lh. To this end, when an approximate diameter of the laser beam Lh is taken as r, the pitch p is approximately within a range of [r/2]<p≦[1.5×r], and it is preferred to scan the laser beam Lh substantially at the same pitch as the diameter r of the laser beam Lh in a given scanning direction y.

The semi-crescent crystal grains b formed by the previous scanning with the laser beam Lh serve as a seed, and crystallization proceeds in the course of scanning with a laser beam Lh adjacent to the previous scanning line. In addition, polycrystallization of the semiconductor thin film 3 proceeds so that grain boundaries a are provided at given pitches p. Crescent-shaped crystal grains b′ combining the semi-crescent-shaped crystal grains b are formed, between the grain boundaries a-a, in align along a direction of extension of the grain boundary a. The crystal grains b′ are in the form of a crescent protruded in a direction opposite to the scanning direction y of the laser beam Lh.

The pitch p permitting laser beams Lh to be scanned in parallel to each other (i.e. a pitch or cycle between grain boundaries a) becomes a factor important for defining the number of crystal grains b′ each combining semi-crescent-shaped crystal grains b provided at a channel portion of the thin film semiconductor device described hereinafter. That is, as will be described hereinafter, it is preferred to set grain boundaries a provided at a channel portion of a thin film semiconductor device at such a great number (cycle number) that variation in transistor characteristics can be made uniform within a range where a carrier mobility is kept. The pitch p is set herein in conformity with the design of the thin film semiconductor device so that a greater number of grain boundaries a are provided at the channel portion within a range not impeding the tact time of the process. According to the pitch p, the spot diameter r of the laser beam Lh in the direction of the pitch p (i.e. a direction vertical to the scanning direction) is set.

More particularly, as will be described in examples appearing hereinafter, it is preferred that the pitch p is set according to a channel length so that the channel portion is provided with about 25 grain boundaries a extended along a channel width.

In such a crystallization step as set out above, it is very important that the characteristics of the grain boundaries a formed by irradiation of the laser beam Lh be made constant. For a factor of making constant characteristics of the grain boundaries a, it is required to keep constant an irradiation energy density of a laser beam at individual irradiation positions, keep the scanning speed constant, keep the pitch p of the laser beams Lh constant, and make the thickness of the semiconductor thin film 3 constant and the like.

In order to make the irradiation energy density of laser beam Lh constant, it is favorable that the laser beam Lh is in a continuously oscillated condition during the course of irradiation of the laser beam Lh at least on an active region. The term “continuously oscillated” used herein may include a case where there is a pause within a range where the temperature of the semiconductor thin film 3 does not lower (e.g. a pause of 50 ns or below). For carrying out such irradiation as set forth above while keeping the irradiation energy density of the laser beam Lh constant, it is desirable to use a laser beam irradiator equipped with a energy feed back function or focus servo function. The feed back function or focus servo function of energy may be set up by known techniques employed in cutting machines for optical disks.

The irradiation of the laser beam Lh on the semiconductor thin film 3 is set within a range where the scanning speed of the laser beam irradiation is kept constant.

The irradiation position of the laser beam Lh against the semiconductor thin film 3 may be moved relatively. More particularly, the substrate on which the semiconductor thin film has been formed may be moved relative to a fixed irradiation position of the laser beam, or the irradiation position of the laser beam may be moved relative to a fixed substrate. Alternatively, both the substrate 1 and the irradiation position of a laser beam may be moved, respectively.

The parallel scanning of the laser beam Lh in the crystallization step may be carried out successively by use of one laser oscillator, or may be carried out by use of a plurality of laser oscillators. Where fabrication of a thin film transistor for driving a display is taken into account, it is preferred to carry out the scanning on a plurality active regions simultaneously. More particularly, it is preferred in view of productivity to use a method wherein laser beams Lh are subjected to multi-irradiation on a plurality of active regions set in align on the surface side of the substrate 1, so that the plurality of active regions are simultaneously crystallized.

In order to realize the multi-irradiation of the laser beams Lh, a semiconductor laser oscillator is appropriately used as an oscillation source for laser beam. Since the semiconductor laser oscillator is much smaller in size than other types of laser oscillators such as an excimer laser, a YAG laser and the like, a plurality of such oscillators can be disposed in one apparatus and are able to generate a rated output power of 200 mW in continuous irradiation.

Using a semiconductor laser oscillator, a flexible device design is enabled for a substrate size by increasing the number of semiconductor lasers corresponding to a large-area substrate. In doing so, there can be obtained a structure wherein a great number of transistors having the same performance are arrayed on a large-sized substrate, with the advantage in the formation of transistors of a larger area having uniform characteristics when compared with a method of controlling grain boundaries by use of a mask as reported in study level.

The crystallization step having set out hereinabove may be carried out not only in an atmosphere of an inert gas, but also in air atmosphere. When the step is carried out in the air atmosphere, the apparatus is prevented from being large in size as a whole.

According to the crystallization step illustrated hereinabove, the crystal grains b which are protruded in a state of being pulled toward the scanning direction y of the laser beam Lh and also toward the scanning center φ are regularly aligned in the scanning direction y and polycrystallized. The shape and alignment pitch of the crystal grains b can be conveniently controlled depending on the irradiation conditions such as the wavelength, scanning speed, irradiation energy and the like of the laser beam Lh. Additionally, the crystal grains b are those obtained by completely melting the semiconductor thin film 3 by irradiation of the laser beam Lh and recrystallizing by liquid phase growth, and are thus good in crystal quality.

When the pitch p of scanning the laser beam Lh is controlled, solidification proceeds while inherently taking over the crystallinity of the crystal grains b formed at a scanning position of an adjacent laser beam Lh, and a crescent-shaped crystal grains b′ that is a combination of the semi-crescent-shaped crystal grains b can be formed between the grain boundaries a aligned at the pitch p. This enables the crystal grains b′ to be regularly aligned in a direction substantially vertical to the scanning direction y.

Accordingly, crystal grains having a good shape accuracy and a good quality are regularly aligned and thus, it becomes possible to form, in the semiconductor thin film, a polycrystalline region wherein a high carrier mobility is controlled in high accuracy.

<Manufacture of a Thin Film Semiconductor Device>

Next, a method for manufacturing a thin film semiconductor device carried out subsequently to such a crystallization method as set out hereinabove is illustrated. There is described herein a method for manufacturing a semiconductor device wherein a plurality of thin film transistors TFTs are formed on the same substrate 1. It will be noted that in the drawings, only one thin film transistor-forming portion is mainly depicted.

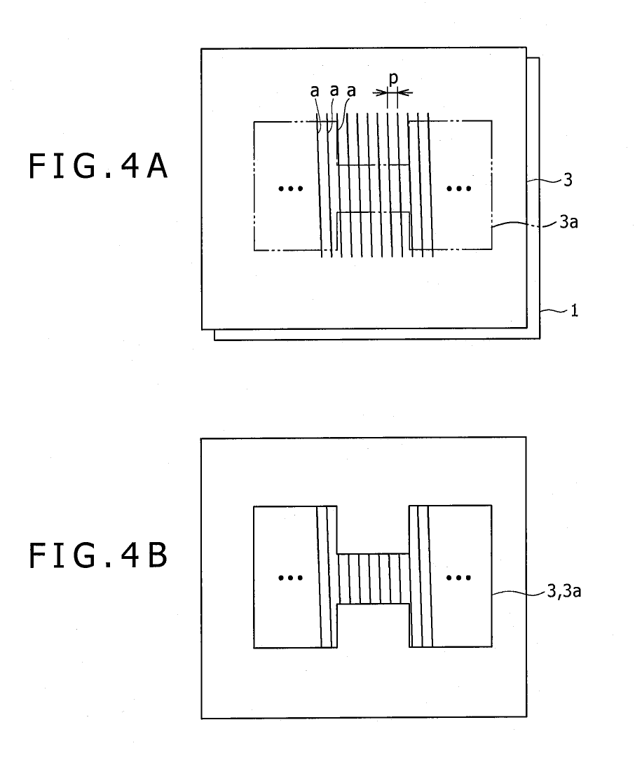

Initially, as shown in FIG. 4A, individual active regions 3a set at the semiconductor thin film 3 on the substrate 1 are selectively crystallized on the entire surface thereof according to the crystallization method set out hereinabove. Grain boundaries a are aligned in parallel to one another across the active region 3a within individual active regions 3a. The grain boundaries a are aligned at such given pitches as stated above.

Next, as shown in FIG. 4B, the semiconductor thin film 3 is pattern etched in a given form so as to leave the crystallized active regions 3a, and the respective active regions 3a are divided as islands of a given form for element isolation. In this case, as shown in the figure, the semiconductor thin film 3 may be pattern etched is such a way that non-crystallized portions of the semiconductor thin film 3 are not left around the active region 3a. Alternatively, the semiconductor thin film 3 may be so pattern etched as to leave non-crystallized portions of the semiconductor thin film 3 around the active region 3a. In this case, the entirety of the crystallized region within an island-patterned region becomes an active region, and an amorphous region left therearound becomes an isolation region. It will be noted that such pattern etching of the semiconductor thin film 3 may be effected prior to the crystallization step. In this case, the respective semiconductor thin films 3 which have been patterned in the form of an island including a region serving as an active region 3a are subjected to such a crystallization step as stated before.

Next, a gate insulating film (not shown) is formed on the substrate 1 so as to cover the patterned active region 3a therewith. This gate insulating film may be made of silicon oxide or silicon nitride and can be formed by a known technique such as ordinary PE-CVD. Besides, known SOG or the like may be formed as a coated insulating film. It will be noted that the formation of the gate insulating film may be made prior to the pattern etching of the semiconductor thin film 3.

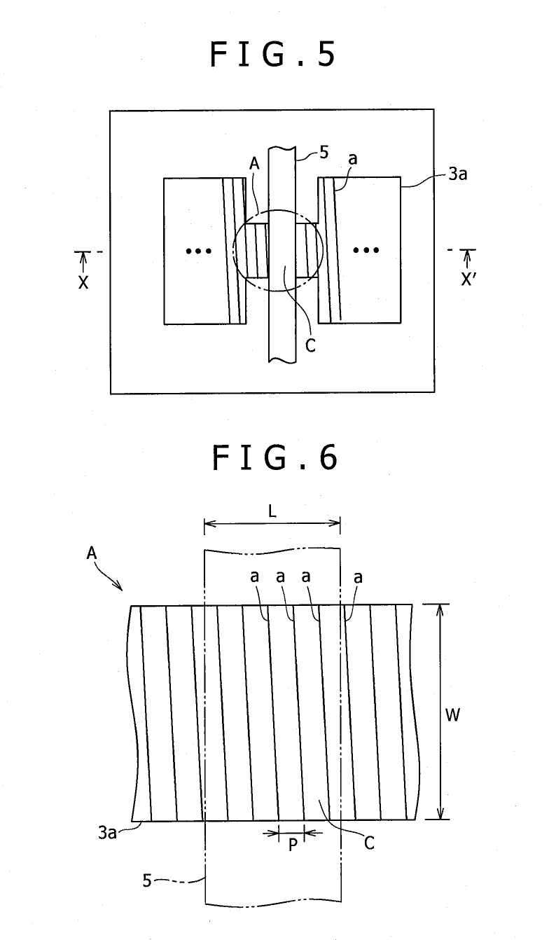

Next, as shown in FIG. 5, a gate electrode 5 that is shaped as passing transversely across the central portion of the respective active regions 3a, each divided as an island, is formed over the gate insulating film. It is important that the gate electrode 5 be formed along a direction of extension of the grain boundaries a. An enlarged view of portion A in FIG. 5 is shown in FIG. 6.

As shown in these figures, the gate electrode 5 is provided across a portion that is designed to have a given width W in the active region 3a, and the width of the active region 3a at a portion thereof which is crossed with the gate electrode 5 becomes a channel width W. In other words, a channel portion C below the gate electrode 5 is provided across the direction of the channel width W.

It is assumed that the line width (corresponding to a channel length L) of the gate electrode 5 is designed based on the standard of the thin film transistor formed herein and that a given number of grain boundaries are arranged therebelow across the direction of the channel width W. So far as thin film transistors having the same characteristics are concerned, it is important that substantially the same number of grain boundaries be provided at the channel portion C. In the practice of the invention, the “substantially the same number” should preferably be within a range of a given number ±1.

If the number of grain boundaries a provided at the channel portion C is smaller in variation with respect to the ratio of the actual number of the boundaries to the given number thereof, the characteristic variation of the thin film transistor can be uniformized. In this sense, a greater number of grain boundaries a provided at the channel portion C is better on the condition that the number is two or over. More particularly, as will be described in examples appearing hereinafter, it is preferred that the pitches p are so set in conformity with the channel L that about 25 grain boundaries a extending in the direction of the channel width W are provided at the channel portion C. It is to be noted here that a greater number of grain boundaries a across the direction of the channel length L at the channel portion C results in a lower carrier mobility along the direction of the channel length L. Thus, a greater number of grain boundaries a is better within a range where the carrier mobility is kept high to an extent.

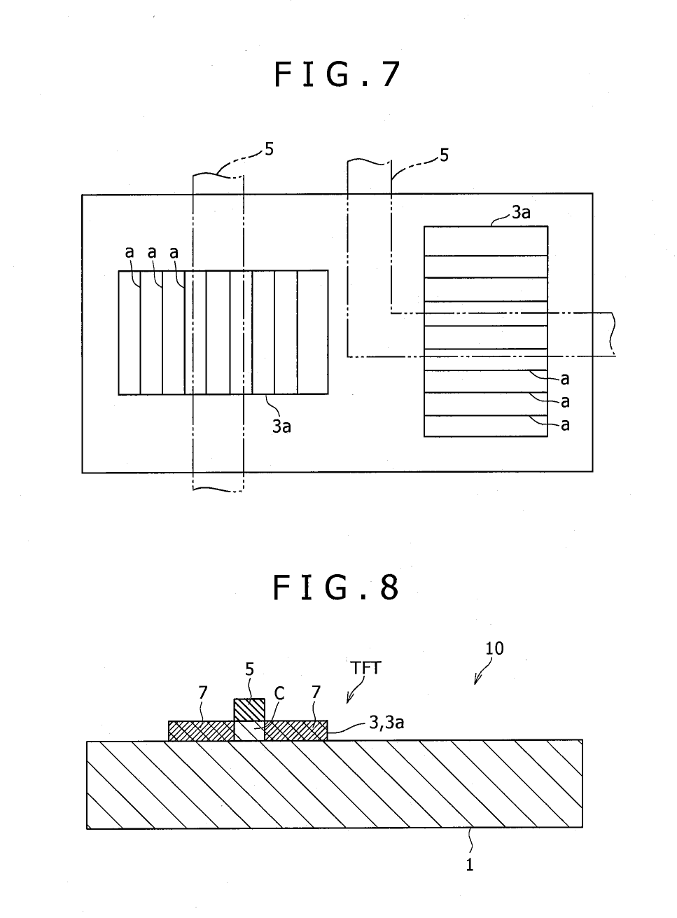

As stated hereinabove, it is important to form the gate electrode 5 in a given state relative to the grain boundaries a provided at the respective active regions 3a. In the crystallization step, as shown in FIG. 7, the scanning direction of the laser beam Lh in individual active regions 3a is set in conformity with a direction of wiring of the gate electrode 5 to coincide the direction of extension of the grain boundaries a with the direction of wiring of the gate electrode 5 as shown in FIG. 7.

For the formation of the gate electrode 5 as stated above, a layer of an electrode material consisting, for example, of aluminium is formed by a sputtering or vacuum deposition method, followed by formation of a resist pattern on the electrode material layer by lithography. Thereafter, the electrode material layer is etched by use of the resist pattern mask to form a pattern for the gate electrode 5.

It will be noted that the formation of the gate electrode 5 is not limited to such a procedure as set out above. For instance, fine particles of a metal may be coated by a printing technique. Alternatively, after etching of the electrode material layer for forming the gate electrode 5, the gate insulating film may be subsequently etched.

Next, as shown in the sectional view of FIG. 8, a source/drain 7 wherein an impurity is self-alignedly introduced into the active region 3a is formed by ion implantation using the gate electrode 5 as a mask and a subsequent annealing treatment. It will be noted that FIG. 8 corresponds to a section taken along line X-X′ in FIG. 5.

In this way, there is formed a channel portion C consisting of an impurity free portion in the active region 3a that has been crystallized below the gate electrode 5. The channel portion C below these source/drain 7 and gate electrode 5 is constituted of the polysilicon obtained by crystallization of the semiconductor thin film 3, so that there can be obtained a thin semiconductor device 10 in which a plurality of top gate thin film transistors TFTs (i.e. polysilicon TFTs) are disposed on the same substrate 1.

If, for example, a liquid crystal display is fabricated as a display wherein such a thin film transistor TFT is used as a switching element, the following steps are further carried out.

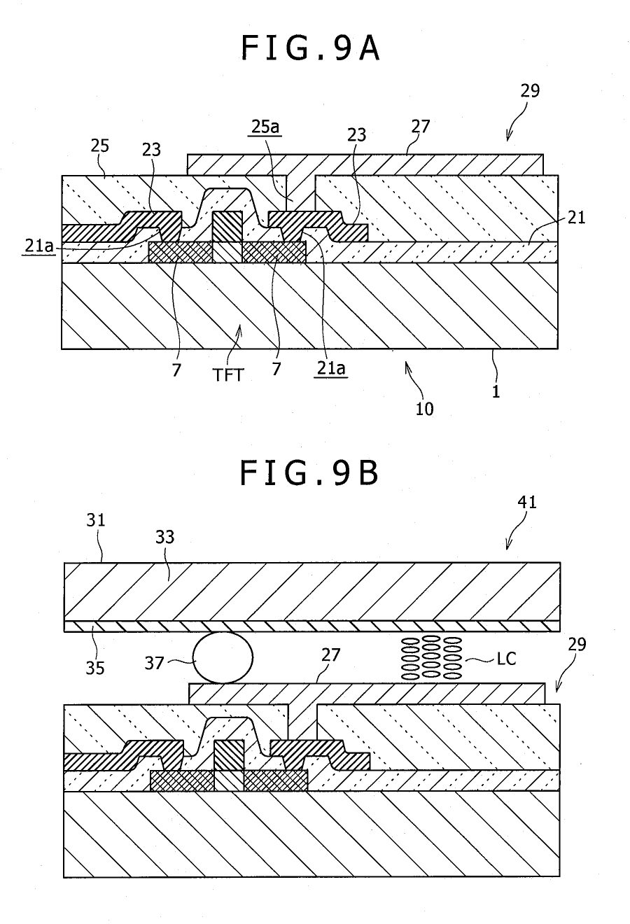

Initially, as shown in FIG. 9A, an interlayer insulating film 21 is formed over the substrate 1 of the thin film semiconductor device 10 so as to cover the thin film transistor TFT therewith. Next, a connection hole 21 arriving at the source/drain 7 of the thin film transistor TFT is formed in the interlayer insulating film 21. A wiring 23 connecting to the source/drain 7 via the connection hole 21a is formed on the interlayer insulating film 21.

A flattened insulating film 25 is formed to cover the wiring 23 therewith, and a connection hole 25a arriving at the wiring 23 is formed in the flattened insulating film 25. Thereafter, a pixel electrode 27 connected to the source/drain 7 via the connection hole 25a and the wiring 23 is formed on the flattened insulating film 25. The pixel electrode 27 is formed as a transparent electrode or a reflection electrode depending on the type of liquid crystal display. The figure is a section of an essential part of one pixel.

Although not shown in the figure, an orientation film covering the pixel electrode 27 is formed on the flattened insulating film to complete a drive substrate 29.

On the other hand, as shown in FIG. 9B, a counter substrate 31 to be disposed in face-to-face relation with the drive substrate 29 is provided. The counter electrode 31 is provided thereon with a common electrode 35 formed on a transparent substrate 33, and the common electrode 35 is covered with an orientation film not shown.

The drive substrate 29 and the counter substrate 31 are arranged in face-to-face relation through a spacer 37 in such a way that the pixel electrode 27 and a common electrode 35 are facing each other. A liquid crystal phase LC is sealedly packed between the substrates 29, 31 kept at a given space by means of the spacer 37 to complete a liquid crystal display 41.

It will be noted that where a organic EL display is fabricated using the drive substrate 29 having such an arrangement as set out hereinabove, the pixel electrode disposed on the drive substrate 29 is provided as an anode (or a cathode), on which organic layers having necessary functions such as a hole injection layer, an emission layer, an electron transport layer and the like are successively formed, followed by further formation, on the organic layers, of a common electrode serving as a cathode (or an anode).

The thin film semiconductor device 10 obtained by use of the crystallization method according to this embedment is arranged such that, referring to FIGS. 5 and 6, the grain boundaries a extending along the gate electrode 5 pass across the channel portion C and are aligned in the direction of the channel length L on a periodic basis, under which carriers passing the channel portion C invariably move across the grain boundaries a located at given pitches. This enables the thin film transistors TFT in the thin film semiconductor device 1 to be well controlled in accuracy with respect to the transistor characteristics (carrier mobility) by controlling the pitches p. Accordingly, the control of the pitch p can lead to high accuracy control of transistor characteristics (carrier mobility) of the thin film transistor TFT in the thin film semiconductor device 1. When a plurality of elements are in coincident with one another with respect to the pitch size and the number of grain boundaries allocated at the channel portion C, the variation in carrier mobility can be suppressed. That is, carriers in the thin film semiconductor device 10 move in a moving direction Xc across the grain boundaries a as shown in FIG. 3. The grain boundary a is a portion, which is finally solidified upon crystallization and in which impurities are concentrated, so that this boundary becomes clearer than the grain boundary established between the scanning directions y of the semi-crescent-shaped grain boundaries b. Because carriers are moved across such clear grain boundaries a by a given number thereof, the transistor characteristics (carrier mobility) of the thin film transistors TFT are better controlled in accuracy than those of a transistor of the type wherein a direction vertical to the moving direction Xc (i.e. a scanning direction y) is designed as a direction of the channel length L.

The crystal state between the grain boundaries a-a is such that crystal grains b′, each extending over between the grain boundaries a-a, are aligned along the grain boundary a. Eventually, no amorphous region is contained, and element characteristics are suppressed from degradation. Because no carrier is passed through the boundary between the crystal grains b′-b′, the carrier mobility along the channel length L is kept high inbetween the grain boundaries a-a.

Accordingly, when the thin film transistors TFTs formed in the thin film semiconductor device are used as a switching element for pixel to constitute a display, the resulting display portion can be prevented from uneven brightness and color shading.

In the above-stated embodiment, as illustrated with reference to FIG. 3, the pitch p for scanning the laser beam Lh is set within such a range that the scanning center φ is not overlapped with the scanning path R of an adjacent laser beam Lh and solidification proceeds inherently to take over the crystallinity of the crystal grains b formed at the scanning position of the adjacent laser beam Lh. In this condition, there has been described a method wherein the semiconductor thin film is polycrystallized so that the crystal grains b′ whose size extends over between the grain boundaries a-a located at the pitch p are aligned in a direction of extension of the grain boundary a. In the practice of the invention, however, the pitch p for scanning the laser beam Lh may be so set that solidification proceeds without inherently taking over the crystallinity of the crystal grains b formed at the scanning position of an adjacent laser beam Lh. In this case, the semiconductor thin film 3 is polycrystallized in such a way that the crystal grain b, amorphous portion and crystal grain b are periodically formed in this order between the grain boundaries a-a provided at a given pitch. Even in this crystallization step, crystallization proceeds in such a way that grain boundaries b are aligned regularly between the grain boundaries a-a of given pitches. The crystal grains b obtained by completely melting the semiconductor thin film and subjecting to liquid phase growth are good in quality.

Even with the active region crystallized while leaving such an amorphous portion, when a gate electrode is provided along the grain boundary a like the above-stated embodiment, there can be obtained a thin film transistor TFT, whose characteristic variation is small, by controlling the accuracy of the transistor characteristic at a high level by the pitch p between the grain boundaries a.

In the above embodiment, there has been illustrated the method of manufacturing a thin film semiconductor device provided with a thin film transistor by application of the polycrystallization method according to one embodiment of the present invention. However, the polycrystallization method is not limited to application to the manufacturing method of a thin film transistor, but is applicable to manufacturing methods of other types of electronic elements. In every case, an electronic element having good characteristic accuracy can be obtained by setting passage of a current across the grain boundary a.

The materials, starting materials, processes and numerical values indicated in the above embodiment are illustrated only by way of example. If necessary, other types of materials and starting material, processes and numerical values different therefrom may also be used.

Examples of the invention are illustrated based on FIG. 3.

### EXAMPLE 1

A 120 nm thick silicon oxide film was formed on a quartz glass substrate according to a plasma CVD method to provide a substrate 1. A 50 nm thick semiconductor thin film made of amorphous silicon was formed on the substrate 1 by a plasma CVD method. Next, in order to eliminate an excess hydrogen ion from the semiconductor thin film 3, annealing treatment (dehydrogenation annealing treatment) was carried out in vacuum at 500° C. for an hour.

Thereafter, the semiconductor thin film 3 is irradiated by a GaN spot beam Lh having a diameter r of about 500 nm, an irradiation energy on the substrate surface (surface irradiation energy) of 12 mW and an effective NA of an objective lens of 0.8 while scanning in parallel to a given scanning direction y. In Example 1, the laser beam Lh irradiation is controlled at pitches p of 400 nm while scanning in parallel to the scanning direction y at a scanning speed v of 1 m/second. It will be noted that irradiation of the laser beam Lh on the semiconductor thin film 3 was invariably controlled by means of a focusing servo so as not to miss the focus upon scanning. In order to make the irradiation energy constant, part of the irradiation energy was monitored to undergo a variation in energy.

When a region crystallized by irradiation with the laser beam Lh was observed through a scanning electron microscope (SEM), it was confirmed that there was obtained a polycrystalline region wherein uniform crescent-shaped crystal grains b′ that were, respectively, protruded toward a direction opposite to the scanning direction y were each regularly aligned between a pair of series grain boundaries a-a provided at pitches (interval) p of 400 nm.

### EXAMPLE 2

The general procedure of Example 1 was repeated except that the irradiation conditions of the laser beam Lh in Example 1 were changed to those including an effective NA of the objective lens of 0.4, a pitch p of 600 nm and a scanning speed v of 3 m/s along the scanning direction.

The region crystallized by the irradiation with the laser beam Lh was observed by a scanning electron microscope (SEM), revealing that that there was obtained a polycrystalline region wherein uniform crescent-shaped crystal grains b′ that were, respectively, protruded toward a direction opposite to the scanning direction y were each regularly aligned between a pair of series grain boundaries a-a provided at pitches (interval) p of 600 nm.

### EXAMPLES 3-1, 3-2

Using the region polycrystallized in Example 1, thin film transistors having channel lengths (gate line width) L of 10 μm and 20 μm and a channel width W of 50 μm were made as shown in Table 1 below. In the thin film transistors of Example 3, a gate wiring 5 was provided in parallel to the grain boundary a as shown in FIG. 5. Thus, as shown in FIG. 3, the gate wiring 5 was provided in parallel to the grain boundary a. In this way, as shown in FIG. 3, the resulting transistor was so arranged that carriers were moved in a moving direction Xc across the grain boundaries a which was finally solidified upon crystallization and wherein impurities were concentrated. The numbers of crystal boundaries at the channel portion of the respective thin film transistors of Examples 3-1, 3-2 were at about 25 and about 50.

TABLE 1

| | | | Number of grain | | | |
|---|---|---|---|---|---|---|
| | Channel | Channel | boundaries | Variation in on | Vth | Mobility |
| | length L | width W | (periodic number) | current ±σ | variation | (cm²/Vs) |
| Example | 10 μm | 50 μm | 25 | ±1.9% | 0.08 V | 26 |
| 3-1 | | | | | | |
| Example | 20 μm | | 50 | ±1.3% | 0.06 V | 26 |
| 3-2 | | | | | | |

GaN laser; NA = 0.8, pitches (pitch periods) of grain boundaries p = 400 nm

The variation in on current of the thus fabricated thin film transistors was measured. The results are also shown in Table 1 above. As will be seen from Table 1, the variation in on current in Example 3-1 is suppressed to ±σ=±1.9, and the variation in on current in Example 3-2 is suppressed to ±σ=±1.3. The variation σ in threshold voltage Vth is suppressed to 0.08 V in Example 3-1 and also to 0.06 V in Example 3-2. It has been confirmed that when the semiconductor thin films polycrystallized according to one embodiment of the invention are used to constitute a channel portion, transistor characteristics can be controlled in high accuracy. Especially, since the variation in on current can be suppressed to within a range of ±σ=3%, it has been confirmed that the use of the thin film transistor as a switching element for pixel electrode in displays using organic electroluminescent elements enables a variation in brightness to be satisfactorily suppressed to a visually non-observable level. Moreover, the comparison between Examples 3-1 and 3-2 reveals that a greater number of grain boundaries a results in the thin film transistor having smaller variations in on current and threshold value and good characteristic accuracy. It has been found that the TFT mobility (carrier mobility) is at 26 cm²/Vs, and thus, good transistor characteristics sufficient for use as a pixel switch can be obtained.

### EXAMPLES 4-1, 4-2

Using a region polycrystallized in the same manner as in Example 2, thin film transistors having a channel length L of 10 μm or 20 μm and a channel width W of 50 μm were fabricated. Like Example 3, these thin film transistors of Example 4 were so arranged that a gate wiring 5 was provided in parallel to the grain boundaries a as shown in FIG. 5 and carriers were moved in a moving direction Xc across the grain boundaries a, which was a portion finally solidified upon crystallization as shown in FIG. 3 and wherein impurities were concentrated. The numbers of the grain boundaries a at channel portions in the thin film transistors of Examples 4-1 and 4-2 were at about 17 and about 33, respectively. It will be noted that in order to suppress an improvement or a variation in on-off characteristic, an alteration was added to the process in Example 4.

TABLE 2

| | | | Number of grain | | | |
|---|---|---|---|---|---|---|
| | Channel | Channel | boundaries | Variation in on | Vth | Mobility |
| | length L | width W | (periodic number) | current ±σ | variation | (cm²/Vs) |
| Example | 10 μm | 50 μm | 17 | ±0.94% | 0.10 V | 18 |
| 4-1 | | | | | | |
| Example | 20 μm | | 33 | ±0.56% | 0.06 V | 18 |
| 4-2 | | | | | | |

GaN laser; NA = 0.4, pitches (pitch periods) of grain boundaries p = 600 nm (with an alteration in process)

The variation in on current of the resulting thin film transistors was measured. The results are shown in Table 2. As shown in Table 2, the variation in on current in Example 4-1 is suppressed to ±σ=±0.94, and the variation in on current in Example 4-2 is suppressed to ±σ=±0.56. The variation σ in threshold voltage Vth is suppressed to 0.10 V in Example 4-1 and also to 0.06 V in Example 4-2. In this way, it has been confirmed that with NA=0.4, when the semiconductor thin films polycrystallized according to one embodiment of the invention are used to constitute a channel portion, transistor characteristics can be likewise controlled in high accuracy. Especially, since the variation in on current can be suppressed to within a range of ±σ=3%, it has been confirmed that the use of the thin film transistor as a switching element for pixel electrode in displays using organic electroluminescent elements enables a variation in brightness to be satisfactorily suppressed to a visually non-observable level. It has been confirmed from the comparison between Examples 4-1 and 4-2 that a greater number of grain boundaries a results in a smaller variation in on current, or results in a thin film transistor having a better characteristic accuracy. The FET mobility (carrier mobility) is at 18 cm²/Vs for both Examples 4-1 and 4-2, revealing that good transistor characteristics sufficient for a pixel switch are obtained.

### COMPARATIVE EXAMPLE

A plurality of thin film transistors were made by application of a crystallization procedure using a conventionally arranged excimer laser.

Initially, after formation of the semiconductor thin film 3 in the same as in Example 1, a KrF excimer laser was optically processed into a line beam having a width of 400 μm along a minor axis and a length of 100 mm along a major axis, and the laser beam was irradiated in such a way that the irradiation position was shifted by pitches of 8 μm along the minor axis in every pulse, while the beams were overlapped on the other regions. At this stage, the energy profile evaluated with respect to a section parallel to the minor axis was controlled to provide a top hat form (i.e. a trapezoidal form). Where irradiation was carried out under such conditions as indicated above, about 50 shots of pulse laser were irradiated on the same region. The irradiation laser was controlled by an attenuator to ensure 25 ns and an energy density corresponding to 310 mJ/cm² in one pulse.

The region that had been crystallized by irradiation of such a laser beam Lh was observed through a scanning electron microscope (SEM), revealing that a polycrystalline region was obtained wherein square-shaped crystals having an about 250 nm side length were aligned regularly in a lattice form.

Using the polycrystallized region, a thin film transistor having a channel length (gate line width) L of 20 μm was fabricated as indicted in Table 3. The channel width W of the thin film transistor was set at 50 μm.

TABLE 3

| | Irradiation | Variation in on | Vth | Mobility |
|---|---|---|---|---|
| | energy beam | current ±σ | variation | (cm²/Vs) |
| Example 3-2 | GaN laser; | +1.3% | 0.06 V | 26 |
| | Na = 0.8 | | | |
| Example 4-2 | GaN laser; | +0.56% | 0.06 V | 18 |
| | Na = 0.4 | | | |
| Comparative | Excimer laser | +6.2% | 0.31 V | 155 |
| Example | | | | |

Channel length L = 20 μm, channel witdth W = 50 μm (the process altered for NA = 0.4)

The variations in on current and mobility of the respective thin film transistors were measures. The results are shown in Table 3. In Table 3, the results of Examples 3-2 and 4-2 are also shown using the same standards as in Comparative Example (i.e. channel length L=20 μm and channel width W=50 μm).

From these results, the variations in on current and threshold voltage Vth of the thin film transistors of Examples 3-2 and 4-2 using the semiconductor thin films crystallized by application of the invention are much smaller than those of Comparative Example using the semiconductor thin film crystallized by means of the excimer laser without application of the invention. It will be noted that although the thin film transistor of Comparative Example is higher with respect to the FET mobility, the values of Examples 3-2 and 4-2 of the invention are good enough for a pixel switch.

It is to be noted that each of the processing procedures according to the other embodiment of the present invention can be interpreted as a method having a sequence of procedures. In addition, each of the sequences of procedures can be interpreted as a program to be executed by a computer or interpreted as a recording medium used for storing such a program.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A method for crystallizing a semiconductor thin film comprising continuously irradiating an energy beam on a semiconductor thin film while scanning at a given speed, wherein
said semiconductor thin film is completely melted and the irradiation conditions of the energy beam are so set that said semiconductor thin film at a central position of the energy beam is finally crystallized in association with the scanning with the energy beam.

2. The method according to claim 1, wherein a series of grain boundaries are formed at scanning centers along each scanning direction.

3. The method according to claim 1, wherein said energy beam is scanned in parallel while keeping a given pitch sufficient not to overlap with said scanning center.

4. The method according to claim 3, wherein said given pitch is set within a range wherein crystallinity of crystal grains formed at the scanning position of an adjacent energy beam are inherently taken over.

5. The method according to claim 4, wherein a series of grain boundaries are provided at the scanning center along the scanning direction and crescent-shaped crystal grains that are protruded toward a direction opposite to the scanning direction of the energy beam are aligned between adjacent grain boundaries.

6. The method according to claim 1, wherein said energy beam has a beam profile of Gaussian curve.

7. The method according to claim 1, wherein said energy beam is used as a spot beam.

8. The method according to claim 1, wherein said energy beam consists of a laser beam oscillated from a semiconductor laser oscillator.
